(19) United States
(12) Patent Application Publication
(10) Pub. No.: US 2024/0118629 A1
(43) Pub. Date: Apr. 11, 2024

(54) METHODS OF FITTING MEASUREMENT DATA TO A MODEL AND MODELING A PERFORMANCE PARAMETER DISTRIBUTION AND ASSOCIATED APPARATUSES

(71) Applicant: ASML NETHERLANDS B.V., Veldhoven (NL)

(72) Inventors: Aliasghar KEYVANI JANBAHAN, Eindhoven (NL); Frans Reinier SPIERING, Arnhem (NL); Jochem Sebastiaan WILDENBERG, Aarle-Rixtel (NL); Everhardus Cornelis MOS, Best (NL)

(73) Assignee: ASML NETHERLANDS B.V., Veldhoven (NL)

(21) Appl. No.: 17/766,585

(22) PCT Filed: Oct. 5, 2020
(86) PCT No.: PCT/EP2020/077807

§ 371 Date: Apr. 5, 2022

(30) Foreign Application Priority Data
Oct. 17, 2019 (EP) 19203752.1
Aug. 31, 2020 (EP) 20193618.4

(51) Int. Cl. G03F 7/00

(52) U.S. Cl. CPC G03F 7/706839; G03F 7/706837; G03F 7/70625; G03F 7/70633; G03F 7/70641

(57) ABSTRACT

A method of processing measurement data relating to a substrate processed by a manufacturing process. The method includes obtaining measurement data relating to a performance parameter for at least a portion of the substrate; and fitting the measurement data to a model by minimizing a complexity metric applied to fitting parameters of the model while not allowing the deviation between the measurement data and the fitted model to exceed a threshold value.

### CROSS-REFERENCE TO RELATED APPLICATIONS

This application claims priority of EP application 19203752.1 which was filed on Oct. 17, 2019 and EP application 20193618.4 which was filed on Aug. 31, 2020 and which are incorporated herein in its entirety by reference.

### FIELD OF THE INVENTION

The present invention relates to methods and apparatus for applying patterns to a substrate in a lithographic process.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In order to monitor the lithographic process, parameters of the patterned substrate are measured. Parameters may include, for example, the overlay error between successive layers formed in or on the patterned substrate and critical linewidth (CD) of developed photosensitive resist. This measurement may be performed on a product substrate and/or on a dedicated metrology target. There are various techniques for making measurements of the microscopic structures formed in lithographic processes, including the use of scanning electron microscopes and various specialized tools. A fast and non-invasive form of specialized inspection tool is a scatterometer in which a beam of radiation is directed onto a target on the surface of the substrate and properties of the scattered or reflected beam are measured. Two main types of scatterometer are known. Spectroscopic scatterometers direct a broadband radiation beam onto the substrate and measure the spectrum (intensity as a function of wavelength) of the radiation scattered into a particular narrow angular range. Angularly resolved scatterometers use a monochromatic radiation beam and measure the intensity of the scattered radiation as a function of angle.

Examples of known scatterometers include angle-resolved scatterometers of the type described in US2006033921A1 and US2010201963A1. The targets used by such scatterometers are relatively large, e.g., 40 μm by 40 μm, gratings and the measurement beam generates a spot that is smaller than the grating (i.e., the grating is underfilled). In addition to measurement of feature shapes by reconstruction, diffraction based overlay can be measured using such apparatus, as described in published patent application US2006066855A1. Diffraction-based overlay metrology using dark-field imaging of the diffraction orders enables overlay measurements on smaller targets. Examples of dark field imaging metrology can be found in international patent applications WO 2009/078708 and WO 2009/106279 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

In performing lithographic processes, such as application of a pattern on a substrate or measurement of such a pattern, process control methods are used to monitor and control the process. Such process control techniques are typically performed to obtain corrections for control of the lithographic process. It would be desirable to improve such process control methods.

### SUMMARY OF THE INVENTION

In a first aspect of the invention, there is provided a method of fitting measurement data to a model, comprising: obtaining measurement data relating to a performance parameter for at least a portion of a substrate; and fitting the measurement data to the model by minimizing a complexity metric applied to fitting parameters of the model while not allowing the deviation between the measurement data and the fitted model to exceed a threshold value.

In a second aspect of the invention, there is provided a method for modeling a performance parameter distribution comprising: obtaining measurement data relating to a performance parameter for at least a portion of a substrate; and modeling the performance parameter distribution based on the measurement data by optimization of a model, wherein the optimization minimizes a cost function representing a complexity of the modeled performance parameter distribution subject to a constraint that substantially all points comprised within the measurement data are within a threshold value from the modeled performance parameter distribution.

In other aspects of the invention, there is provided a computer program comprising program instructions operable to perform the method of the first aspect when run on a suitable apparatus, a processing device comprising a processor and storage with such a computer program and a lithographic apparatus with such a processing device.

Further aspects, features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

Embodiments of the invention will now be described, by way of example, with reference to the accompanying drawings in which:

FIG. 1 depicts a lithographic apparatus together with other apparatuses forming a production facility for semiconductor devices;

FIG. 2 shows exemplary sources of processing parameters;

FIG. 3 illustrates schematically a current method of determining corrections for control of a lithographic apparatus;

FIG. 4 is an overlay plot conceptually illustrating support vector machine regression optimization;

FIG. 5(a) and (b) are cumulative yield plots of percentage yield against overlay error in the x and y directions respectively;

FIG. 6 is a conceptual schematic of the “model assumption” describing a mapping between an input space and feature space and a fitting from the feature space to an output space; and

FIG. 7 is a plot of output space OS (value for a parameter of interest) against input space IS (wafer location) for an actual fingerprint and a KB SVM estimate obtained according to an embodiment of the invention.

### DETAILED DESCRIPTION

Before describing embodiments of the invention in detail, it is instructive to present an example environment in which embodiments of the present invention may be implemented.

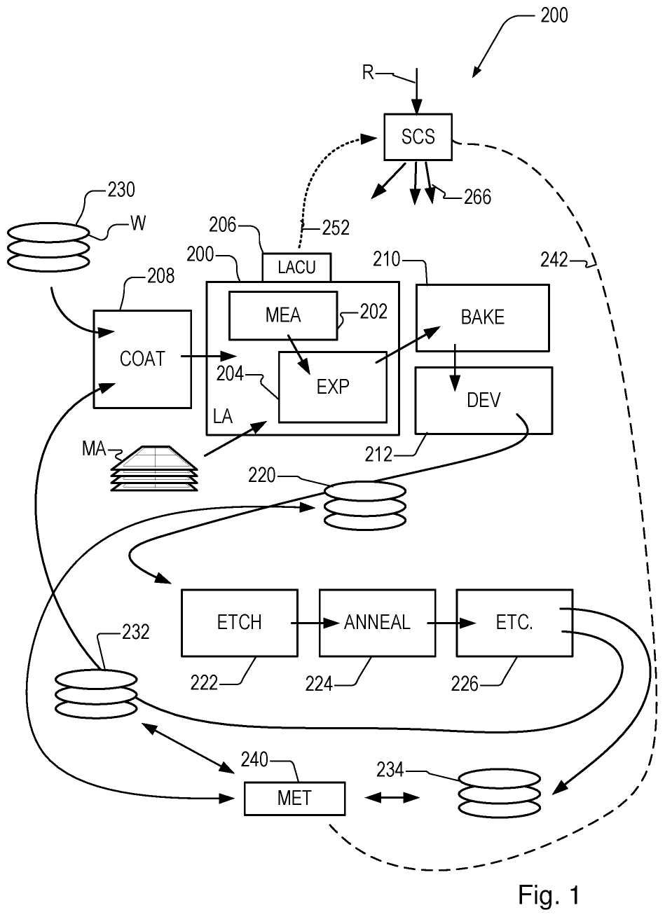

FIG. 1 at 200 shows a lithographic apparatus LA as part of an industrial production facility implementing a high-volume, lithographic manufacturing process. In the present example, the manufacturing process is adapted for the manufacture of for semiconductor products (integrated circuits) on substrates such as semiconductor wafers. The skilled person will appreciate that a wide variety of products can be manufactured by processing different types of substrates in variants of this process. The production of semiconductor products is used purely as an example which has great commercial significance today.

Within the lithographic apparatus (or “litho tool” 200 for short), a measurement station MEA is shown at 202 and an exposure station EXP is shown at 204. A control unit LACU is shown at 206. In this example, each substrate visits the measurement station and the exposure station to have a pattern applied. In an optical lithographic apparatus, for example, a pattern transfer unit or projection system is used to transfer a product pattern from a patterning device MA onto the substrate using conditioned radiation and a projection system. This is done by forming an image of the pattern in a layer of radiation-sensitive resist material.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. The patterning MA device may be a mask or reticle, which imparts a pattern to a radiation beam transmitted or reflected by the patterning device. Well-known modes of operation include a stepping mode and a scanning mode. As is well known, the projection system may cooperate with support and positioning systems for the substrate and the patterning device in a variety of ways to apply a desired pattern to many target portions across a substrate. Programmable patterning devices may be used instead of reticles having a fixed pattern. The radiation for example may include electromagnetic radiation in the deep ultraviolet (DUV) or extreme ultraviolet (EUV) wavebands. The present disclosure is also applicable to other types of lithographic process, for example imprint lithography and direct writing lithography, for example by electron beam.

The lithographic apparatus control unit LACU which controls all the movements and measurements of various actuators and sensors to receive substrates W and reticles MA and to implement the patterning operations. LACU also includes signal processing and data processing capacity to implement desired calculations relevant to the operation of the apparatus. In practice, control unit LACU will be realized as a system of many sub-units, each handling the real-time data acquisition, processing and control of a subsystem or component within the apparatus.

Before the pattern is applied to a substrate at the exposure station EXP, the substrate is processed in at the measurement station MEA so that various preparatory steps may be carried out. The preparatory steps may include mapping the surface height of the substrate using a level sensor and measuring the position of alignment marks on the substrate using an alignment sensor. The alignment marks are arranged nominally in a regular grid pattern. However, due to inaccuracies in creating the marks and also due to deformations of the substrate that occur throughout its processing, the marks deviate from the ideal grid. Consequently, in addition to measuring position and orientation of the substrate, the alignment sensor in practice must measure in detail the positions of many marks across the substrate area, if the apparatus is to print product features at the correct locations with very high accuracy. The apparatus may be of a so-called dual stage type which has two substrate tables, each with a positioning system controlled by the control unit LACU. While one substrate on one substrate table is being exposed at the exposure station EXP, another substrate can be loaded onto the other substrate table at the measurement station MEA so that various preparatory steps may be carried out. The measurement of alignment marks is therefore very time-consuming and the provision of two substrate tables enables a substantial increase in the throughput of the apparatus. If the position sensor IF is not capable of measuring the position of the substrate table while it is at the measurement station as well as at the exposure station, a second position sensor may be provided to enable the positions of the substrate table to be tracked at both stations. Lithographic apparatus LA may for example is of a so-called dual stage type which has two substrate tables and two stations—an exposure station and a measurement station—between which the substrate tables can be exchanged.

Within the production facility, apparatus 200 forms part of a “litho cell” or “litho cluster” that contains also a coating apparatus 208 for applying photosensitive resist and other coatings to substrates W for patterning by the apparatus 200. At an output side of apparatus 200, a baking apparatus 210 and developing apparatus 212 are provided for developing the exposed pattern into a physical resist pattern. Between all of these apparatuses, substrate handling systems take care of supporting the substrates and transferring them from one piece of apparatus to the next. These apparatuses, which are often collectively referred to as the track, are under the control of a track control unit which is itself controlled by a supervisory control system SCS, which also controls the lithographic apparatus via lithographic apparatus control unit LACU. Thus, the different apparatus can be operated to maximize throughput and processing efficiency. Supervisory control system SCS receives recipe information R which provides in great detail a definition of the steps to be performed to create each patterned substrate.

Once the pattern has been applied and developed in the litho cell, patterned substrates 220 are transferred to other processing apparatuses such as are illustrated at 222, 224, 226. A wide range of processing steps is implemented by various apparatuses in a typical manufacturing facility. For the sake of example, apparatus 222 in this embodiment is an etching station, and apparatus 224 performs a post-etch annealing step. Further physical and/or chemical processing steps are applied in further apparatuses, 226, etc. Numerous types of operation can be required to make a real device, such as deposition of material, modification of surface material characteristics (oxidation, doping, ion implantation etc.), chemical-mechanical polishing (CMP), and so forth. The apparatus 226 may, in practice, represent a series of different processing steps performed in one or more apparatuses. As another example, apparatus and processing steps may be provided for the implementation of self-aligned multiple patterning, to produce multiple smaller features based on a precursor pattern laid down by the lithographic apparatus.

As is well known, the manufacture of semiconductor devices involves many repetitions of such processing, to build up device structures with appropriate materials and patterns, layer-by-layer on the substrate. Accordingly, substrates 230 arriving at the litho cluster may be newly prepared substrates, or they may be substrates that have been processed previously in this cluster or in another apparatus entirely. Similarly, depending on the required processing, substrates 232 on leaving apparatus 226 may be returned for a subsequent patterning operation in the same litho cluster, they may be destined for patterning operations in a different cluster, or they may be finished products to be sent for dicing and packaging.

Each layer of the product structure requires a different set of process steps, and the apparatuses 226 used at each layer may be completely different in type. Further, even where the processing steps to be applied by the apparatus 226 are nominally the same, in a large facility, there may be several supposedly identical machines working in parallel to perform the step 226 on different substrates. Small differences in set-up or faults between these machines can mean that they influence different substrates in different ways. Even steps that are relatively common to each layer, such as etching (apparatus 222) may be implemented by several etching apparatuses that are nominally identical but working in parallel to maximize throughput. In practice, moreover, different layers require different etch processes, for example chemical etches, plasma etches, according to the details of the material to be etched, and special requirements such as, for example, anisotropic etching.

The previous and/or subsequent processes may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly a manufacturing facility in which litho cell LC is located also includes metrology system which receives some or all of the substrates W that have been processed in the litho cell. Metrology results are provided directly or indirectly to the supervisory control system SCS. If errors are detected, adjustments may be made to exposures of subsequent substrates, especially if the metrology can be done soon and fast enough that other substrates of the same batch are still to be exposed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

Also shown in FIG. 1 is a metrology apparatus 240 which is provided for making measurements of parameters of the products at desired stages in the manufacturing process. A common example of a metrology station in a modern lithographic production facility is a scatterometer, for example a dark-field scatterometer, an angle-resolved scatterometer or a spectroscopic scatterometer, and it may be applied to measure properties of the developed substrates at 220 prior to etching in the apparatus 222. Using metrology apparatus 240, it may be determined, for example, that important performance parameters such as overlay or critical dimension (CD) do not meet specified accuracy requirements in the developed resist. Prior to the etching step, the opportunity exists to strip the developed resist and reprocess the substrates 220 through the litho cluster. The metrology results 242 from the apparatus 240 can be used to maintain accurate performance of the patterning operations in the litho cluster, by supervisory control system SCS and/or control unit LACU 206 making small adjustments over time, thereby minimizing the risk of products being made out-of-specification, and requiring re-work.

Additionally, metrology apparatus 240 and/or other metrology apparatuses (not shown) can

be applied to measure properties of the processed substrates 232, 234, and incoming substrates 230. The metrology apparatus can be used on the processed substrate to determine important parameters such as overlay or CD.

Various techniques may be used to improve the accuracy of reproduction of patterns onto a substrate. Accurate reproduction of patterns onto a substrate is not the only concern in the production of ICs. Another concern is the yield, which generally measures how many functional devices a device manufacturer or a device manufacturing process can produce per substrate. Various approaches can be employed to enhance the yield. One such approach attempts to make the production of devices (e.g., imaging a portion of a design layout onto a substrate using a lithographic apparatus such as a scanner) more tolerant to perturbations of at least one of the processing parameters during processing a substrate, e.g., during imaging of a portion of a design layout onto a substrate using a lithographic apparatus. The concept of overlapping process window (OPW) is a useful tool for this approach. The production of devices (e.g., ICs) may include other steps such as substrate measurements before, after or during imaging, loading or unloading of the substrate, loading or unloading of a patterning device, positioning of a die underneath the projection optics before exposure, stepping from one die to another, etc. Further, various patterns on a patterning device may have different process windows (i.e., a space of processing parameters under which a pattern will be produced within specification). Examples of pattern specifications that relate to a potential systematic defect include checks for necking, line pull back, line thinning, CD, edge placement, overlapping, resist top loss, resist undercut and/or bridging. The process window of all or some (usually patterns within a particular area) of the patterns on a patterning device may be obtained by merging (e.g., overlapping) process windows of each individual pattern. The process window of these patterns is thus called an overlapping process window. The boundary of the OPW may contain boundaries of process windows of some of the individual patterns. In another words, these individual patterns limit the OPW. These individual patterns can be referred to as “hot spots” or “process window limiting patterns (PWLPs),” which are used interchangeably herein. When controlling a lithography process, it is possible, and typically economical, to focus on the hot spots. When the hot spots are not defective, it is likely that all the patterns are not defective. The imaging becomes more tolerant to perturbations when values of the processing parameters are closer to the OPW if the values of the processing parameters are outside the OPW, or when the values of the processing parameters are farther away from the boundary of the OPW if the values of the processing parameters are inside the OPW.

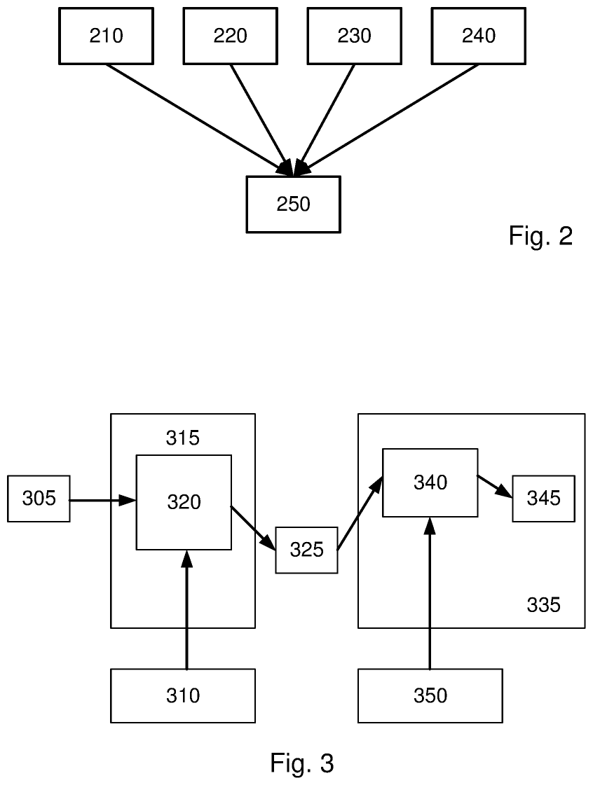

FIG. 2 shows exemplary sources of processing parameters 250. One source may be data 210 of the processing apparatus, such as parameters of the source, projection optics, substrate stage, etc. of a lithography apparatus, of a track, etc. Another source may be data 220 from various substrate metrology tools, such as a substrate height map, a focus map, a critical dimension uniformity (CDU) map, etc. Data 220 may be obtained before the applicable substrate was subject to a step (e.g., development) that prevents reworking of the substrate. Another source may be data 230 from one or more patterning device metrology tools, patterning device CDU map, patterning device (e.g., mask) film stack parameter variation, etc. Yet another source may be data 240 from an operator of the processing apparatus.

Control of the lithographic process are typically based on measurements fed back or fed forward and then modelled using, for example interfield (across-substrate fingerprint) or intrafield (across-field fingerprint) models. Within a die, there may be separate functional areas such as memory areas, logic areas, contact areas etc. Each different functional area, or different functional area type may have a different process window, each with a different processes window center. For example, different functional area types may have different heights, and therefore different best focus settings. Also, different functional area types may have different structure complexities and therefore different focus tolerances (focus process windows) around each best focus. However, each of these different functional areas will typically be formed using the same focus (or dose or position etc.) setting due to control grid resolution limitations.

The lithographic control is typically performed using offline calculation of one or more set-point corrections for one or more particular control degrees of freedom, based on (for example) measurements of previously formed structures. The set-point corrections may comprise a correction for a particular process parameter, and may comprise the correction of a setting of a particular degree of freedom to compensate for any drift or error such that the measured process parameter remains within specification (e.g., within an allowed variation from a best set-point or best value; for example, an OPW or process window). For example, an important process parameter is focus, and a focus error may manifest itself in a defective structure being formed on a substrate. In a typical focus control loop, a focus feedback methodology may be used. Such a methodology may comprise a metrology step which may measure the focus setting used on a formed structure; e.g., by using diffraction based focus (DBF) techniques in which a target with focus dependent asymmetry is formed such that the focus setting can be subsequently determined by measurement of the asymmetry on the target. The measured focus setting may then be used to determine, offline, a correction for the lithographic process; for example a positional correction for one or both of the reticle stage or substrate stage which corrects the focus offset (defocus). Such an offline positional correction may then be conveyed to the scanner as a set-point best focus correction, for direct actuation by the scanner. The measurements may be obtained over a number of lots, with an average (over the lots) best focus correction applied to each substrate of one or more subsequent lots. Similar control loops are used in the other two dimensions (substrate plane) to control and minimize overlay error.

FIG. 3 illustrates such a methodology. It shows product information 305, such as product layout, illumination mode, product micro-topography etc., and metrology data 310 (e.g., defocus data or overlay data measured from previously produced substrates) being fed to an offline processing device 315 which performs an optimization algorithm 320. The output of the optimization algorithm 320 is one or more set-point corrections/offsets 325, e.g., for actuators which control reticle stage and/or substrate stage positioning (in any direction, i.e., in the x, y and/or z directions, where x and y are the substrate plane direction and z is perpendicular to x and y) within scanner 335; the set-point corrections 325 being calculated to compensate for any offsets/errors (e.g., defocus, dose or overlay offsets/errors) comprised within the metrology data 310. A control algorithm 340 (e.g., leveling algorithm) calculates control set-points 345 using substrate specific metrology data 350. For example, a leveling exposure trajectory (e.g., determining a relative movement or acceleration profile for positioning of the substrate stage relative to the reticle stage during the lithographic process) may be calculated using leveling data (e.g., a wafer height map) and outputs positional set-points 345 for the scanner actuators. The scanner 335 directly applies, equally for each substrate, the set-point corrections 325 to the calculated set-points 345. In other control arrangements, the optimization may be performed within the scanner to provide optimized corrections on a per-wafer basis (wafer-to-wafer control).

The optimization algorithm (e.g., as performed within an offline processing device and/or scanner) may be based on a number of different merit functions, one for each control regime. As such, in the example described above, a levelling (or focus) merit function is used for the focus control (scanner z direction control), which is different to an overlay (scanner x/y direction control) merit function, a lens aberration correction merit function etc. In other embodiments, control may be co-optimized for one or more of these control regimes.

Regardless of the control regime and control aspect being optimized, existing optimization methods often rely on performing a least squares (e.g., root-mean-square (RMS)) regression based optimization or similar such regression. Such methods result in all the measurements being given equal importance, although some measurements suffer more from noise and uncorrectable errors than other ones. More importantly, existing methods may attempt to correct dies having a small overlay error and as such will yield anyway, potentially at the expense of pushing otherwise marginally yielding dies out of specification. When all the measurements have the same weight, the estimator tries to find a compromise between all the measurements to reduce the error everywhere. This means that even the easily yielding points are pushed down, which can push other dies out of specification. Such methods are sensitive to noisy data and lack of measurement points. Also, such methods can estimate overly high values for the fingerprints, which later in the optimization may waste the actuator potential (actuation range) for no additional benefit. Note that the larger the estimated fingerprint parameters, the higher the risk of reaching the limit of the actuator capability in the optimization.

Such RMS type regression methods have a tendency to overfit or underfit, and there is no direct control on the level of fitting. In case of overfitting, the calculated fingerprints exceed the actual value which can be very problematic. Normalized model uncertainty (nMU) may be used, together with projection ratios, to predict and prevent overfitting by reducing the complexity of the model; however these methods limit the choice of model. For example, it is common knowledge that a 3^{rd} order model cannot be fitted to only two data points, etc. However, this can be made possible by adding other constraints or cost functions to the fitting problem. This practice, which is called regularization in machine learning, can help to fit a model that, in a probabilistic sense, has lower out-of-sample error.

To address these issues, it is proposed to use a modified version of a support vector machines (SVM) regression technique instead of a least-squares fitting in the estimation part of an optimization. Such an optimization technique will use a different cost function and different set of constraints compared to the existing least squares method.

As such, disclosed herein is a method for controlling a lithographic apparatus configured to provide product structures to a substrate in a lithographic process, the method comprising: obtaining metrology data related to the substrate; and optimizing a control merit function for the lithographic apparatus based on said metrology data, said optimizing comprising performing a support vector machines regression on said control merit function.

Aims of such a method comprise determining fingerprints such that:
The fingerprints are robust to noisy data.
The fingerprints can deal comfortably with less or sparse metrology data. This can reduce the metrology load and increase throughput.
The fingerprints are as small as possible (but not smaller) so that actuator range is not wasted. This can free up the budget for other corrections.
No overfitting is possible: To keep the out-of-sample error as close as possible to the in-sample error, machine learning techniques (including the SVM) try to achieve a model that has least possible variance to the sampling. This is done via margin maximization and regularization. Such a technique would statistically have a small error at the non-measured locations. By contrast a least squared method only minimizes the error for in-sample errors (measured points).
The estimated fingerprint model describes the measured data sufficiently well.

The SVM regression method works by essentially sacrificing/compromising where the overlay value is small (e.g., within a threshold ϵ), and using that freedom to correct dies with larger errors (e.g., which would otherwise be almost yielding dies). More specifically, the SVM regression method attempts to find a function ƒ(x) that has at most ε deviation from known values (e.g., training data) for all of the training data, and at the same time is as flat (non-complex) as possible. In other words, errors are accepted and ignored provided they are less than ϵ. Deviations larger than this are not tolerated in the basic SVM regression; however, in practical circumstances the resultant optimization problem will typically not be feasible. To address this, slack variables ξᵢ, ξᵢ* may be used to accommodate outliers.

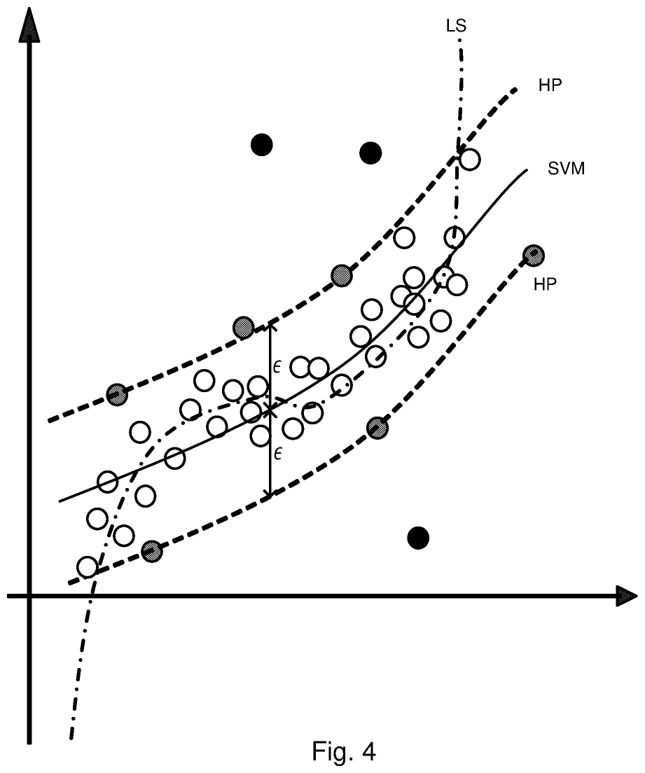

FIG. 4 conceptually illustrates the SVM regression. FIG. 4 is an overlay plot (e.g., a plot of an overlay component (e.g., dx or dy) against a wafer location coordinate) with each point on the Figure representing an overlay error value. Note that this is only a 2D plot for ease of representation, in actual overlay modeling, both dx and dy overlay components will be modelled as a function of x and y. The parameter ϵ defines an acceptable margin or overlay error, and can be chosen by a user. The white points inside of the dashed lines HP (which denote the extent of the hyperplane defined by the margin ϵ), i.e., those points having a magnitude smaller than ϵ, do not contribute to the cost. In other words these values are essentially ignored when performing the SVM regression; they are considered to represent an overlay that is good enough and therefore not requiring any correction. The gray points are the points closest to the hyperplane; these are called the support vector points. The support vector points are the basis functions which determine the SVM regression (solid line) SVM. The black points are outliers or error support vectors. Slack variables are used to cope with these, such that their distance from dashed lines are minimized (e.g., first norm). In this way, the model SVM produced by SVM regression only depends on a subset of the training data, because the cost function for building the model ignores any training data that is close (within a threshold ϵ) to the model prediction. For contrast, a least-squares fit LS to the same data points is also shown (dot-dash line), which displays signs of overfitting (being overly complex).

A highly simplified mathematical description of the difference between the least square regression and SVM regression will now be described. Although the example uses overlay as a direct use case, the methodology is in no way specific for estimating overlay fingerprints. The SVM regression techniques disclosed herein are equally suitable for fingerprint estimation of any parameter such as focus, critical dimension (CD), alignment, edge placement error, etc. and/or any optimization comprised within lithographic process control.

For both least squares and SVM regression cases, the model can be stated as:

Ax=b

Where A is the so called “Design Matrix”, generated by evaluating the overlay (or other parameter) model on the measurement grid; the term x is the so called “model parameter”, and is a vector comprising the fingerprint parameters: e.g. “k-parameters” or parameters of a typical 6 parameter model (x/y translation parameters: Tx, Ty, symmetric/asymmetric magnification parameters: Ms, Ma, symmetric/asymmetric rotation parameters: Rs, Ra) or of any other suitable model for modeling a fingerprint; and the term b is a vector comprising all the measured overlay values in both x and y directions (i.e., metrology data). The aim of a least squares regression optimization is to find the model parameters x which minimizes Ax−b; i.e., the least square method minimizes the 2-norm of the error in the equation Ax=b:

$${min}_{x} ‖ Ax - b ‖$$

where ∥⋅∥ is the 2-norm operator. Note that the italicized “x” will be used throughout to denote the model parameter term, in contrast to the non-italicized “x” which denotes a spatial coordinate.

By contrast, in an SVM regression technique, the optimization aims to minimize the “complexity” of the fingerprint parameters subject to the constraint that all the measurements are “sufficiently explained” by the model.

The complexity of fingerprint parameters can be defined as the 2-norm of the vector holding

the parameter values except for any zeroth order parameters (e.g., such as the translation parameters Tx and Ty in an overlay model). To better understand the concept of complexity in this context, the following concepts from machine learning should be understood:
Generalization: suppose a model is to be fitted onto a data set. A first proportion (e.g., the first half) of the data is used to train (fit) your model and a second proportion (e.g., the second half) of the data is used to validate the model once trained. The first proportion of the data is typically referred to as in-sample data and the second proportion of the data is typically referred out-of-sample data. A ratio between the in-sample error and out-of-sample error is a measure of generalizability of the model; i.e., a measure of how successful the model is at representing the out-of-sample data which was not used (not taken into account) in the fitting process.
VC-dimension: Vapnik-Chervonenkis (VC) dimension is a measure of complexity of the model. In neural networks the VC dimension is normally measured using dichotomies. Generally: the lower the VC dimension, the more generalizable is the fit. For example: A second order model on one dimensional data comprising a total of three parameters can be better generalized than a third order model with a total of four parameters fitted on the same data (in such a case the number of the parameters is equal to the VC dimension). It should be appreciated that, while it is commonly stated that the number of the parameters should not exceed the number of measurements, this is not generally true. It is actually the number of VC dimensions (not parameters) which should be fewer than the number of the measurements. The number of parameters is not necessarily equal to the VC dimension. For example, it is possible to fit a 1000 parameter model with data comprising 10 measurements; however, the complexity of the fit, as defined with VC dimension should not be higher than 10.

Fitting a full infinite dimensional model onto a given data set remains possible; a common practice in fitting nonlinear models such as ƒ(A, x)=b is by using kernel functions. By such techniques, it is possible to keep the VC dimension low while the model itself has infinite number of parameters, which means that the out-of-sample error can be kept low.

Keeping the out-of-sample error close to in-sample error can be achieved using regularization techniques. Regularization is a technique which discourages the learning (or fitting) of a complex or flexible model (i.e., it favors simpler models), so as to keep the VC dimension low and avoid the risk of overfitting.

The VC dimension of a model can be minimized based on an optimization on the 2-norm of the parameter values except zeroth order terms (i.e., the bias). For the example of overlay, this means minimizing all the parameter values except the linear translation parameters (Tx and Ty). Later, it will become apparent why the VC dimension reduces by this optimization, such that it is low enough to be generalizable even if the overlay model has a very high number of parameters.

In order to keep the equations simple, assume for this example that the overlay data model can be written as:

Ax+t=b

Where t represents zeroth order (translation terms). Then the optimization problem for low complexity becomes a minimization of the 1-norm or 2-norm of the model parameters; e.g.:

$$\\ {min}_{x} ‖ x ‖$$

Subject to the criterion that all the measurements are sufficiently explained by the model. Note that ∥x∥ is only one example of a complexity metric for minimization in the methods described herein. In other embodiments, a weighted norm may be minimized, for example:

$$\\ {min}_{x} ‖ {Q}^{1 / 2} x ‖ = {min}_{x} \sqrt{{x}^{T} Qx}$$

where Q is any Positive-Definite square matrix size of x. Q can contain information on the expense of using a certain model parameter. For example, if it is undesirable to use a first parameter p1, but instead compensate for this (as much as possible) using a second parameter p2, a high weight may be given to the Q element relating to parameter p1 with respect to the Q element relating to parameter p2, such that the estimator is less likely to use parameter p1 as parameter p2. Q can also be used to assign use relative costs to pairs or sets of parameters using off-diagonal elements of the Q matrix.

This criterion means that, for each and every measurement j:

$$\\ \vert {\sum }_{i} {A}_{ji} {x}_{i} + t - {b}_{j} \vert < ϵ$$

where |⋅| signifies the absolute value. This constraint states that all the measured overlay values are fully explained by the model with an accuracy better than ϵ.

However, outliers and residuals are almost inevitable. Therefore, such outliers should be accommodated, yet penalized at the same time. This can be done by the provision of slack variables, with which the optimization problem can be written as:

$$\\ {min}_{x , ξ} ( ‖ x ‖ + C {\sum }_{j} ( {ξ}_{j} + {ξ}_{j}^{*} ) )$$

### Subject to:

$$\\ {\sum }_{i} {A}_{ji} {x}_{i} - {b}_{j} < ϵ + {ξ}_{j}$$

$$\\ {\sum }_{i} {A}_{ji} {x}_{i} - {b}_{j} > - ϵ - {ξ}_{j}^{*}$$

$$\\ {ξ}_{j} , {ξ}_{j}^{*} > 0$$

Where ξ and ξ* are the upper and lower slack variables allowing for outliers and C is outlier penalization coefficient, also called as “complexity coefficient”. The constant C (>0) determines the trade-off between the flatness (complexity) of the fit and the degree to which deviations larger than ε are tolerated through penalizing the outliers. The higher the complexity coefficient, the greater the freedom for the model to choose a complex model, to better represent the in-sample data. At one extreme, irrespective of the overlay model used to generate the A matrix, if C=0, the solution will simply be only zeroth order translation. At the other extreme, C equals infinity would mean that the maximum error is always maintained smaller than a certain value regardless of the complexity; e.g., similar to an L_{∞} norm (absolute maximum) optimization (L_{∞}<ϵ).

The optimization should determine a complexity coefficient C, margin ε and slack variable ξ, such that that all the measured data is either represented by the model within an accuracy smaller than the (e.g., user defined) margin ϵ; or else, where this is not possible, their error (ξ) should be kept at a minimum provided that the solution does not become too complex as a result.

In order to convert this optimization problem to a quadratic programming optimization the method of Lagrange multipliers can be employed. Such a method converts a constrained problem into a form such that the derivative test of an unconstrained problem can still be applied. At any stationary point of the function that also satisfies the equality constraints, the gradient of the function at that point can be expressed as a linear combination of the gradients of the constraints at that point, with the Lagrange multipliers acting as coefficients. The relationship between the gradient of the function and gradients of the constraints leads to a reformulation of the original problem, known as the Lagrangian function. As such, Lagrange multipliers α, α*, η, η* can be defined, and the Lagrangian function L written as:

$$\\ L := \frac{1}{2} ‖ x ‖ + C {\sum }_{j} ( {ξ}_{j} + {ξ}_{j}^{*} ) - {\sum }_{j} ( {η}_{j} {ξ}_{j} + {η}_{j}^{*} {ξ}_{j}^{*} ) + {\sum }_{j} {α}_{j} ( {A}_{ji} {x}_{i} + t - {b}_{j} - ϵ - {ξ}_{j} ) + {\sum }_{j} {α}_{j}^{*} ( - {A}_{ji} {x}_{i} - t + {b}_{j} - ϵ - {ξ}_{j}^{*} )$$

This Lagrangian function L can be simply converted to a simple quadratic programming in the adjoint formulation, where the inner product of the data forms a cost function and C forms an inequality constraint:

$$\\ min \{ \begin{matrix}- \frac{1}{2} {\sum }_{k , l}^{all} ( {α}_{k} - {α}_{k}^{*} ) ( {α}_{l} - {α}_{l}^{*} ) 〈 {A}_{k} , {A}_{l} 〉 \\ - ϵ {\sum }_{j}^{all} ( {α}_{j} - {α}_{j}^{*} ) + {\sum }_{j}^{all} {b}_{j} ( {α}_{j} - {α}_{j}^{*} )\end{matrix}$$

### Subject to:

$$\\ {α}_{j}^{*} ∈ [ 0 , C ]$$

$$\\ {\sum }_{j} ( {α}_{j} - {α}_{j}^{*} ) = 0$$

The original model parameters x are a linear combination of the design matrix and the achieved optimum Lagrange multipliers:

$$\\ {x}_{i} = {\sum }_{j} ( {α}_{j} - {α}_{j}^{*} ) {A}_{ji}$$

After solving the optimization problem, it becomes apparent that most of the α^{(*)} (i.e., αⱼ and αⱼ*) values are zero. Only few of the α^{(*)} values comprise non-zero values. The number of the non-zero α^{(*)} values is the VC dimension of this problem. Because of this, the entire model parameters can be written as a linear combination of only a few measurement points: xᵢ=Σⱼ(αⱼ−αⱼ*)Aⱼᵢ.

Even if the overlay model was of a very high order (e.g., of the order of 100 parameters), if only few (e.g., 6) α^{(*)} values are non-zero, the complexity of the model (the VC dimension) is 6, and the model is as generalizable as a six parameter (‘6par’) model. However both the in-sample and out-of-sample errors are as low as a 100 parameter model.

Each of the data values (columns of the matrix A) which correspond to a non-zero α^{(*)} and also contribute to the fingerprint parameters x is called a support vector, because they are vectors which support the hyperplane in the high dimensional space (hence the name support vector machine). In the specific example of the previous paragraph, there are 6 support vectors, each one of which being 100 dimensional and which together support a 100 dimensional hyperplane. It should be appreciated that it is not the error which is optimized, nor the parameters, but α^{(*)}. The bias (or translation parameter for overlay case) is determined after optimization (e.g., using the Karush-Kuhn-Tucker (KKT) condition), which is not necessarily equal to the average of the data.

To summarize, it is proposed to use SVM regression to fit parameter fingerprints (e.g., overlay) as part of a lithographic process optimization. SVM regression in its currently known form cannot be directly applied to fingerprint data, due to its 2D nature whereas SVM in its general form can only deal with one dimensional data. Therefore, described herein is a modified version of the SVM technique which can be applied to 2D fingerprint data.

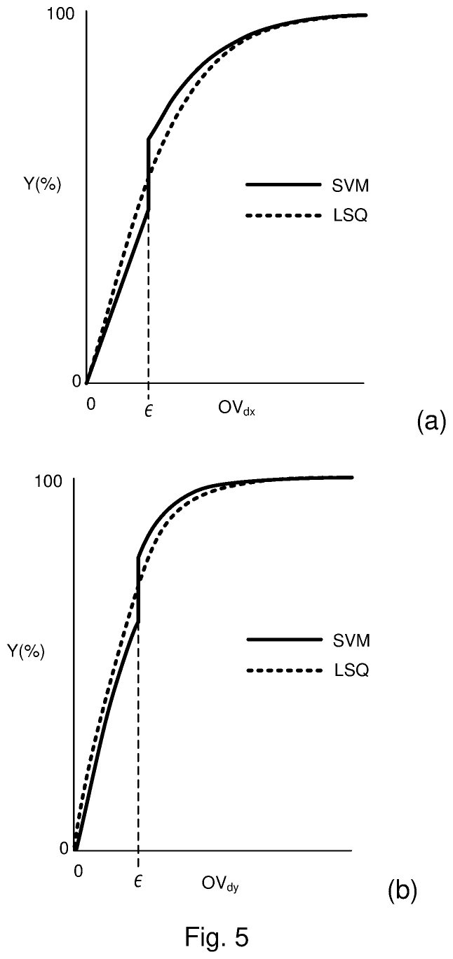

FIG. 5 shows an example of the result of SVM modeling with a target margin ϵ of 0.45 nm, compared with modeling using least square fitting (LSQ) method. FIGS. 5(a) and 5(b) each show cumulative plots of in-sample errors (i.e., modeled errors at measurement points). The y-axis shows a cumulative number (as a percent) of measurement points below or equal to an in-sample error value of the overlay values OV_{dx}, OV_{dy} (FIGS. 5(a) and 5(b) respectively). As SVM ignores measurement points within the target margin ϵ, SVM modeling typically results in fewer measurement points having an in-sample error below the target margin ϵ compared to modeling using LSQ method. However, SVM modeling typically results in multiple measurement points having an in-sample error which is on the target margin (corresponding to the vertical section at ϵ for each plot). Thus, SVM modeling is expected to result in better modeling (i.e., more measurement points having modeled errors less or equal to the target margin) than modeling using an LSQ method, as SVM sacrifices on low-error points in order to gain on high-error points. Therefore SVM can improve yield by concentrating all correction potential on larger errors without wasting correction potential on small errors.

In overlay modeling (or modeling for another parameter of interest) generally and in the case of the aforementioned embodiments, a fingerprint model needs to be assumed prior to fitting; e.g., Zernike, regular polynomial or any other model. However, by definition it is not possible to know/guarantee that there is no model mismatch. This means that the underlying overlay is not necessarily accurately modeled with the “assumed” overlay model.

Having a fixed predefined fingerprint model requires a certain sampling layout which suits the assumption. For example, it is not possible to update a fingerprint for a first class of models (e.g., a Correction Per Exposure (CPE) fingerprint which determines corrections per field) with a sparsely sampled overlay measurement, e.g., appropriate only for a second class of model. With a fixed predefined “assumed” model, the model granularity is categorical. For example, model classes may include a per-field model, an average field model, a scan up scan down (SUSD) dependent model, a per-wafer, a per-chuck, or a per-lot model. But a model cannot be partly one of these classes; e.g., it may not be “slightly per-field”, “slightly per-wafer” etc. Such an inflexible approach is not ideal. The real overlay will be the result of machine overlay and process fingerprints, which do not necessarily follow model definitions. For example, reticle heating induced variations occur partly from field to field (inter-field component); however, they may also occur partly across an average field (intra-field component). Chuck 1 may be slightly different to Chuck 2, but the lens contribution for both chucks may be the same, etc. These chuck contributions from different chucks may be modelled using models with different granularities. However, using a kernel, the kernel may model the reticle heating and/or these different chuck contributions without defining the granularities of the fingerprints.

The essence of the embodiment described below is the use of a kernel to define a class of models in an abstract manner, rather than directly specifying a model to be fitted. Subsequent to this, an optimal kernel function may be formed out of the class of models defined by the kernel, while simultaneously fitting to the formed kernel function.

In order to understand the idea behind this concept, it is important to carefully examine the estimation/modeling task. The basic concept in modeling of overlay/focus/cd (or other parameter of interest) is:
Assume that the measured overlay/focus/cd values are describable with a set of (for example polynomial) functions.
Calculate the coefficients of these (for example polynomial) functions by minimizing an error indicator.

For example, it may be assumed that a particular model fingerprint can be described with regular polynomials. It may be assumed that each field, or wafer, or lot, has a different fingerprint. Each of these statements is an assumption. Based on the assumption, weights or “fingerprint parameters” assumed in the model are calculated; e.g., by minimizing (e.g., the second norm) of the collective overlay error at measurement locations. In such a method, the model complexity that can be assumed and the number of fingerprint parameters are limited by the number (and validity) of the measurement points. Mathematically, this is true for a least squares solution, however, it is not necessarily so for SVM.

It is proposed in this embodiment to replace both of the aforementioned assumption and calculation steps with a new optimization problem which mathematically is equivalent to assuming an “infinite parameter” (or at least a very high dimensional) model. A very high dimensional model may comprise for example: over 500 dimensions, over 1000 dimensions, over 5000 dimensions, over 50000 dimensions over 5 million dimensions or infinity. There are many advantages for this, including:
Model mismatch can be avoided or at least reduced. No model needs be chosen and no human input is required (thus removing a failure mode). Instead parameter of interest knowledge and context is accumulated in a so-called Kernel function
It is possible to use some process/scanner knowledge to give abstract meaning to context, and therefore, estimate very highly complex and accurate fingerprints from sparse data.
It is possible to give meaning for time in context, enabling prediction for future lots, instead of doing time filtering. Note that time filtering reduces the noise at the cost of adding phase lag, or some delay which reduces performance.
The fingerprints are robust to noisy data (due to epsilon intensive dead-band).
The method can more easily deal with less and non-uniform metrology data. This can reduce the metrology load and increase the fab throughput.
The modeled fingerprints are as small as possible so that the actuator ranges are used more efficiently. For example, where two mathematical descriptions can describe the same fingerprint, the smallest one may be chosen such that actuation capacity is not wasted. This can free up the budget for other corrections.
No overfitting and no underfitting: To keep the out-of-sample error as close as possible to the in-sample error, machine learning techniques (including SVM) try to achieve a model that has least possible variance to the sampling. This is done via margin maximization and regularization. Such a technique may statistically have a small error at the non-measured locations.
The estimated fingerprint model describes the measured data sufficiently well. Fingerprints that were not possible to capture by any other model are easily captured with this technique.

This technique also holds the same behavior in yield plot exist as for the normal SVM.

### Mathematical Description:

In SVM, a nPar model can be fitted to m number of measurements, even if m is less than n. To illustrate the fitting of an infinite parameter model to a finite number of measurements, an Overlay example will be given. Although the example uses overlay as a direct use case, the methodology is in no way specific for overlay and can be used for other parameters of interest PoI such as Focus, CD, alignment, edge placement, etc.

As already stated, the Overlay estimation problem is normally defined as:

Ax=b

where A is the so called “Design Matrix”, generated by evaluating the “overlay model” on the measurement grid. x is a vector containing the fingerprint parameters: e.g. k-parameters and b is a vector containing all the measured overlay values both in x and y directions.

The model assumption is comprised within design matrix A: each row of this matrix refers to a certain measurement location on the wafer and each column of this matrix represents an specific basis function (e.g. a single term of polynomial) that is assumed in the model.

Aᵢⱼ=j^{th} basis function evaluated on i^{th} measurement point

The basis functions are each typically a nonlinear function of the location. For example, each basis function of a 38 par per-field model is a (non-linear) function of location of the point in field with respect to center of the field (x_{ƒ}, and y_{ƒ})

ƒ(x_{ƒ},y_{ƒ})=x_{ƒ}^{p}y_{ƒ}^{k}

where p and k are powers of polynomials. Assuming a model, or modeling step, in fact means assuming a function which maps each point on the wafer (per context parameter associated with the wafer), onto a another point in a higher dimensional space. For example, a 38-par per-field, per-chuck model for a wafer with 100 fields takes any 5 dimensional vector (measurement point in each field; 2D for Xf, Yf, 2D for Xw, Yw and 1D for ChuckID) then maps it onto a 7600 dimensional space (38 Par* 2 Chucks*100 fields=7600). This formally reads as:

∀ᵢ: ϕ(x_{ƒi},y_{ƒi},x_{wi},y_{wi},ChuckIDᵢ)∈{ [symbol] ,{1,2}} [symbol] A_{i,j}∈ [symbol] ;j=1→nPar

where nPar means number of parameters. This function effects per measurement point i. Formally:
X=x_{ƒi}, y_{ƒi}, x_{wi}, y_{wi}, ChuckIDᵢ∈{ [symbol] , {1, 2}} is called the input space,
[symbol] is called the feature space, and
the value of overlay (dx, dy) is called the output space.

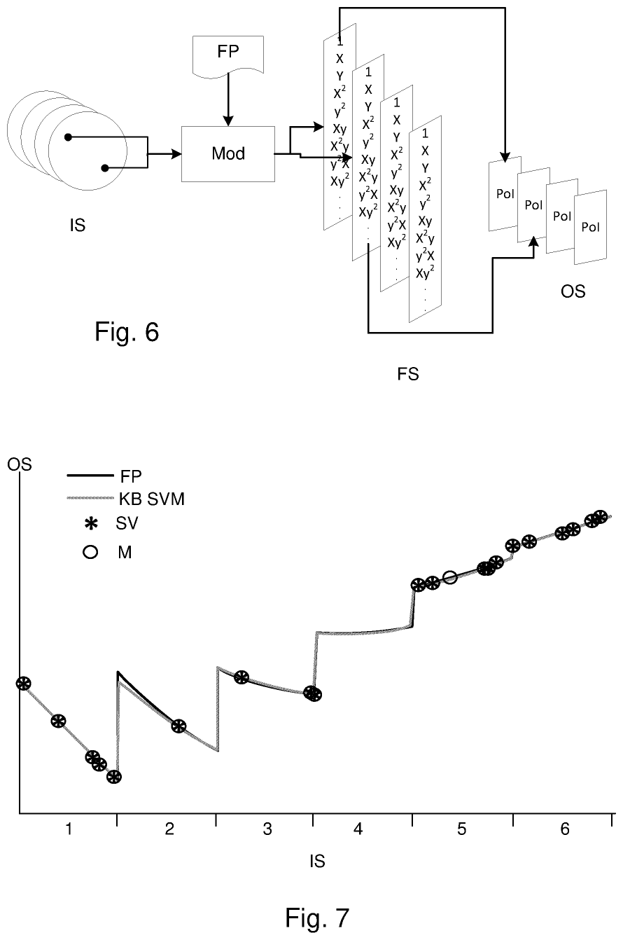

FIG. 6 conceptually illustrates the model assumption. The Figure shows an implicit mapping of a layout, comprising wafer coordinates and context, from an input space IS to a higher dimensional space or feature space FS via a modelling step MOD (the assumption) using fingerprint models FP. The feature space FS comprises rows of the design matrix A. Then a linear fit is attempted between the feature space FS and output space OS comprising a measure or estimated overlay or other parameter of interest PoI value.

The question postulated herein is what is required from design matrix A, and is the design matrix even needed at all?

In Least square optimization, (and many other forms of regression) it can be shown that the following is typically required:

P=AA_{(nPar×nPar)}^{T}

which should be full rank, or made so using a regularization technique such as Tikhonov, etc. (depending on the model).

However for SVM, the following is required:

K=A^{T}A_{(nMeas×nMeas)}

which may not be full rank and where nMeas is the number of measurements. In the context of SVM, the K matrix is called the Kernel. In fact, Kᵢⱼ is the inner product of i and j element (i.e. vector) (respectively associated with measurement point i and j) in the feature space. Inner product in mathematics is the definition of similarity of two vectors. Therefore Kᵢⱼ describes how similar the measurement point i is to measurement point j.

Different models with different number of parameters can output different values; however, models will preserve a sense of similarity while the kernel remains the same size and the values of the kernel do not change much for the different models. For example, both a first model and a second model should agree up to a point on the similarity of two points on the wafer. As such, if two points have the same value using one model, they should not have wildly differing values using the other model.

Using a Kernel, it is not necessary to first construct the design matrix (A) in order to construct K. The K matrix can be generated by first generating a Kernel function k analytically; e.g.:

k(Xᵢ,Xⱼ)=ϕ^{T}(Xᵢ)ϕ(Xⱼ)

where ϕ is defined as a mapping function. Note that any model can be converted to a kernel using above equation, simply multiply each element of the mapping function, associated with the model, evaluated at Xᵢ, Xⱼ and sum them up (i.e. calculate the inner product of two vectors i and j in the feature space spanned by the mapping function ϕ). For example,

ϕ=[1,x,x²,x³]

k(X₁,X₂)=(1+X₁X₂+X₁²X₂²+X₁³X₂³)

However, for a kernel to be valid, it is not necessary that it corresponds to any model. Following this, the function can be evaluated on each and every measurement location:

Kᵢⱼ=k(Xᵢ,Xⱼ)

which is exactly identical to first constructing the design matrix A, and then multiplying it by itself. This trick allows kernel matrixes to be created even if it is very difficult or even impossible to create the design matrix A, for example, when a kernel describes an inner product of infinite dimension space.

Mathematically, the only requirement for this Kernel to be valid is that it should be positive semi-definite over spaces for which the kernel function k is defined. Therefore, there is no requirement to check if the mapping function ϕ actually exists. This means that it is possible to use Kernels which do not correspond to any overlay model, as long as they are positive semi-definite. The kernel may be constructed such that it corresponds to an infinite dimensional model.

In an embodiment, a kernel may describe a distance metric. The distance metric may be an inner product of two elements in the feature space. Alternatively, the distance metric may be the sum of absolute values of the differences between components of two elements in the feature space (e.g. k(X₁, X₂)=|1−1|+|X₁−X₂|+|X₁²−X₂²|+|X₁³−X₂³|).

To understand the Kernel idea, the following example is given. For an example measurement in 2 dimensional space:

X=[x_{ƒ},y_{ƒ}]^{T} (e.g., only one field)

and the Kernel function is:

k(Xⱼ,Xᵢ)=(1+Xᵢ^{T}Xⱼ)²

which represents a model as:

ϕ=[1,x_{ƒ},y_{ƒ},x_{ƒ}²,y_{ƒ}²,x_{ƒ}y_{ƒ}]

which is all the polynomials up to second order.
Similarly, the kernel function

k(Xⱼ,Xᵢ)=(1+Xᵢ^{T}Xⱼ)ⁿ

represents all the polynomials up to n^{th} order.

Similarly, a Gaussian kernel:

$$\\ k ( {X}_{j} , {X}_{i} ) = exp ( - \frac{{‖ {X}_{i} - {X}_{j} ‖}^{2}}{2 {σ}^{2}} )$$

represents a model with infinite number of parameters, where σ is an arbitrary length scale. Of course, it would be impossible to generate a design matrix with infinite number of rows; however, it is nonetheless possible to generate a Kernel which represents the inner product in that specific infinite dimensional space.

Naturally, by not having any model, it is not possible to have fingerprint parameters. However, solving the kernel based SVM yields a (non-parametric) function which describes the overlay at any location of the wafer. This is not a linear combination of fingerprint parameters and polynomial base function, instead, the overlay function is:

$$\\ \{ \begin{matrix}dx \\ dy\end{matrix} \} = {\sum }_{p = 1}^{nSPV} ( {α}_{p} - {α}_{p}^{*} ) k ( {X}_{p} , X ) + \{ \begin{matrix}tx \\ ty\end{matrix} \}$$

This problem may be solved based on an optimization problem. The input of the optimization may be:
the kernel function: k(Xⱼ, Xᵢ) (more about selection of kernel function will be described); and
Measurement data points (e.g., coordinates in input space and overlay value)

The output of the optimization problem may be:
the translation terms tx, ty.
the support vector coefficients αₚ and αₚ*.
the support vectors Xₚ
the number of support vectors nSPV.

The optimization problem may take the form:

$$\\ min \{ \begin{matrix}- \frac{1}{2} {\sum }_{i , j}^{nMeas} ( {α}_{i} - {α}_{i}^{*} ) ( {α}_{j} - {α}_{j}^{*} ) {K}_{ij} \\ - ϵ {\sum }_{i}^{nMeas} ( {α}_{i} - {α}_{i}^{*} ) + {\sum }_{i}^{nMeas} {\{ \begin{matrix}dx \\ dy\end{matrix} \}}_{i} ( {α}_{i} - {α}_{i}^{*} )\end{matrix}$$

subject to:

$$\\ {α}_{i}^{\text{(*} )} ∈ [ 0 , C ]$$

$$\\ {\sum }_{i}^{nMeas} ( {α}_{i} - {α}_{i}^{*} ) = 0$$

and where ϵ is as an arbitrary estimate/guess of the noise (thickness of the ribbon) and C is a regularization factor as has already been defined above.

In the same way as the earlier described linear embodiment, the Kernel based SVM comprises minimizing the complexity metric of the fingerprint parameters subject to the constraint that all the measurements are sufficiently explained. For Kernel based SVM the complexity of fingerprint parameters may be conceptually the same as defined in the linear embodiment (e.g., as the 2-norm of the vector holding the parameter values (e.g., except for Tx and Ty)); however it is not explicitly calculated.

After solving the optimization problem, it will be noticed that most of the α^{(*)}s are zero. Only few α^{(*)} will have nonzero values. The number of the non-zero α^{(*)} is the VC dimension of this problem. Because the entire model parameters can be written as a linear combination of few measurement points. After solving the optimization, the function may be reported, or evaluated on any (dense) layout and the overlay values reported.

To summarize, the following table shows the algorithm difference between SVM and kernel based SVM (KB SVM):

| | (Linear)SVM | KB SVM |
|---|---|---|
| Assumption | $\{ \begin{matrix}dx \\ dy\end{matrix} \} = Ax + \{ \begin{matrix}Tx \\ Ty\end{matrix} \}$ | $\{ \begin{matrix}d x \\ d y\end{matrix} \} = w Φ ( x ) + \{ \begin{matrix}T x \\ T y\end{matrix} \}$ |
| | x refers to parameters | There is an underlying model (optionally), |
| | | but it is not explicitly defined a priori. So |
| | | w will not be found. |
| | | x refers to coordinates. |
| Optimization | $min \{ \begin{matrix}- \frac{1}{2} {\sum }_{i , j}^{nMeas} ( {α}_{i} - {α}_{i}^{*} ) ( {α}_{j} - {α}_{j}^{*} ) 〈 {A}_{i} , {A}_{j} 〉 \\ - ϵ {\sum }_{i}^{all} ( {α}_{i} - {α}_{i}^{*} ) + {\sum }_{i}^{all} {\{ \begin{matrix}d x \\ d y\end{matrix} \}}_{j} ( {α}_{i} - {α}_{i}^{*} )\end{matrix}$ | $min \{ \begin{matrix}- \frac{1}{2} {\sum }_{i , j}^{nMeas} ( {α}_{i} - {α}_{i}^{*} ) ( {α}_{j} - {α}_{j}^{*} ) {K}_{ij} \\ - ϵ {\sum }_{i}^{all} ( {α}_{i} - {α}_{i}^{*} ) + {\sum }_{i}^{all} {\{ \begin{matrix}d x \\ d y\end{matrix} \}}_{i} ( {α}_{i} - {α}_{i}^{*} )\end{matrix}$ |
| | Subject to | Subject to |
| | $\begin{matrix}{α}_{i}^{\text{(*} )} ∈ [ 0 , C ] \\ {\sum }_{i} ( {α}_{i} - {α}_{i}^{*} ) = 0\end{matrix}$ | $\begin{matrix}{α}_{i}^{\text{(*} )} ∈ [ 0 , C ] \\ {\sum }_{i} ( {α}_{i} - {α}_{i}^{*} ) = 0\end{matrix}$ |
| | $\{ \begin{matrix}T x \\ T y\end{matrix} \} Calculated from KKT condition ( both cases )$ | |
| Solution | $1 - {x}_{j} = {\sum }_{p = 1}^{nSPV} ( {α}_{p} - {α}_{p}^{*} ) {A}_{pi}$ | $\{ \begin{matrix}d x \\ d y\end{matrix} \} = {\sum }_{p = 1}^{nSPV} ( {α}_{p} - {α}_{p}^{*} ) k ( {X}_{p} , X ) + \{ \begin{matrix}T x \\ T y\end{matrix} \}$ |
| | $2 - \{ \begin{matrix}d x \\ d y\end{matrix} \} = A x + \{ \begin{matrix}T x \\ T y\end{matrix} \}$ | |

### Selection of Kernel:

An important question is: what should the Kernel function be, and how does the Kernel function affect the results? The Kernel function is a measure of similarity (in this case between individual measurements) based on domain knowledge. Note that this concept is about the framework of kernel based estimation and not any specific implementation (or any specific kernel function).

The proposed concept results in a tool which can be used for different purposes; however each time a smart choice of Kernel should preferably be made.

In a first example, the kernel may comprise a partially per-field, partially global interfield, and partially global intra-field, all the polynomials, up to the order N.

First of all, a 1D example will be given. The underlying pattern is a polynomial/sine/cosine function of x_{ƒ}, x_{w}, where all the fields are different, but are related to each other by a sine/cosine relationship. This pattern is sampled/measured in random positions (e.g. circles), and fed to the KB-SVM with a polynomial Kernel:

K(xᵢ,xⱼ)=(1+xᵢ^{T}xⱼ)⁴

where xᵢ=[x_{w}, x_{ƒ}] at measurement i.

The measurement layout is quite random, e.g., possibly such that one or more fields have no measurement. However, KB-SVM with a simple 4th order kernel is capable of correctly fitting the data, even for the field for which there is no measurement. Interestingly, it may even ignore or throw out a measurement if it deems that it does not have any extra information to add.

FIG. 7 is a plot of output space OS (value for a parameter of interest) against input space IS (wafer location over fields 1 to 6) illustrating this. A first plot (black line) is the actual fingerprint FP and a second plot (gray line) is a KB-SVM estimate using the polynomial Kernel in this example. Field 4 comprises no measurement data M and therefore no support vector SV. However the estimate KB SVM is very close to the actual fingerprint FP for all fields including field 4.

Applying the same idea in a 2D Overlay example, it is possible to obtain CPE (per field corrections) based on a data set which is only suitable for global modeling using other techniques. The main advantage of this technique is that it tries to find the underlying pattern out of any (non-complete) set of data that is available. More specifically, assuming a measurement layout where some fields are measured densely, but the other fields are measured sparsely, it would be desirable to use KB-SVM to estimate a CPE for this layout. The idea is that every field is a bit different, and these differences are captured (to a degree) with the existing measurements. The kernel is then constructed to capture this measure of similarity. The kernel does not need to be exact, but should have the necessary components. For example the following kernel may be used:

$$\\ K ( {x}_{i} , {x}_{j} ) = ( samefield ( {x}_{i} , {x}_{j} ) + 0.1 ) {( 1 + {x}_{{f}_{i}}^{T} {x}_{{f}_{j}} )}^{5} + exp ( - \frac{‖ {x}_{{w}_{i}} - {x}_{{w}_{j}} ‖}{0.01} )$$

$$\\ where samefield ( {x}_{i} , {x}_{j} ) = \{ \begin{matrix}1 from same field \\ 0 not same field\end{matrix}$$

The first part of the kernel essentially says that two points are 10 times more similar if they are in the same field, than if they are not. This means: partially (0.1) global-intra-field and partially (1) per-field. The second part says that any intra-field fingerprint can be any 5th order polynomial. The third part of kernel says the interfield part of fingerprint should be continuous (Gaussian kernel).

A drawback of this technique is that it requires an expert to construct a good kernel. Although the numbers in kernel do not matter that much, its structure does matter.

In another example, an Interfield Gaussian kernel is proposed. A local interfield fingerprint may be such that it may not be captured with existing fingerprint models because very high order models are needed; the fingerprint being too local. Additionally, existing per field models give a discrete, non-exact estimate. In order to model such a fingerprint, a Gaussian radial kernel may take the form:

$$\\ ( {X}_{j} , {X}_{i} ) = exp ( - \frac{{‖ {X}_{i} - {X}_{j} ‖}^{2}}{2 {σ}^{2}} )$$

where Xᵢ=[x_{w}, y_{w}] is the location of the point on the wafer, and σ is a constant, (larger than the distance between two points, smaller than footprint of the fingerprint.

The per field model gives a discrete estimate of a physical fingerprint which should not be discrete.

The kernel based approach requires good definition of the kernels. This may be based on expert knowledge, or found using a data driven approach. Another approach may comprise a multi-kernel estimation.

In summary, this kernel based embodiment comprises constructing or choosing a kernel to describe one or more criteria (e.g. closeness among two wafer coordinates) for evaluating the measured fingerprint. The kernel defines one or more classes of models (e.g., combined multiple model classes, possibly according to a weighting) from which a function is generated for densifying the measured fingerprint while considering different granularity of models (e.g., per cell, per die, per sub-filed, per field, per wafer, per lot, etc.). SVM with the kernel determines a function to describe the measured fingerprint.

The embodiments may further be described using the following clauses:
1. A method of fitting measurement data to a model, comprising:
   obtaining measurement data relating to a performance parameter for at least a portion of a substrate; and
   fitting the measurement data to the model by minimizing a complexity metric applied to fitting parameters of the model while not allowing a deviation between the measurement data and the fitted model to exceed a threshold value.
2. A method according to clause 1, wherein the complexity metric is 1-norm or 2-norm of the model parameters, or is 1-norm or 2-norm of weighted model parameters.
3. A method according to clause 1 or 2, wherein the complexity metric further comprises one or more slack variables to accommodate any outliers comprised within the measurement data, said deviation between the measurement data and the fitted model being allowed to exceed the threshold value for said outliers, and one or more coefficients for weighting the slack variables.
4. A method according to clause 3, wherein the one or more coefficients is a complexity coefficient which can be selected and/or optimized to determine the degree to which the outliers are penalized against the complexity of the fitting.
5. A method according to any preceding clause, wherein said measurement data comprises at least two-dimensional measurement data.
6. A method according to clause 5, wherein said fitting step comprises determining a two-dimensional fingerprint describing a spatial distribution of the performance parameter.
7. A method according to any preceding clause, further comprising defining Lagrange multipliers for said complexity metric, and converting the complexity metric into a Lagrangian function using the Lagrange multipliers.
8. A method according to clause 7, comprising converting the Lagrangian function into quadratic programming optimization.
9. A method according to clause 7 or 8, wherein said fitting step comprises determining model parameters as a linear combination of a design matrix and optimized values for said Lagrange multipliers.
10. A method according to any preceding clause, wherein said measurement data describes one or more of: a characteristic of the substrate; a characteristic of a patterning device which defines a pattern which is to be applied to the substrate; a position of one or both of a substrate stage for holding the substrate and a reticle stage for holding the patterning device; or a characteristic of a pattern transfer system which transfers the pattern on said patterning device to the substrate.
11. A method according to any preceding clause, wherein said measurement data comprises one or more of: overlay data, critical dimension data, alignment data, focus data, and levelling data.
12. A method according to any preceding clause, wherein the complexity metric relates to controlling a lithographic process, to optimize control of one or more of: exposure trajectory control in the directions parallel to a substrate plane; exposure trajectory control in the direction perpendicular to the substrate plane, lens aberration correction, dose control and laser bandwidth control for a source laser of the lithographic apparatus.
13. A method according to clause 12, comprising controlling the lithographic process according to said optimized control.
14. A method according to clause 12 or 13, wherein the lithographic process comprises exposure of a layer on a substrate, forming part of a manufacturing process for manufacturing an integrated circuit.
15. A method according to any preceding clause, the complexity metric is operable to minimize one or more of: overlay error, edge placement error, critical dimension error, focus error, alignment error and levelling error.
16. A method for modeling a performance parameter distribution comprising:
   obtaining measurement data relating to a performance parameter for at least a portion of a substrate; and
   modeling the performance parameter distribution based on the measurement data by optimization of a model, wherein the optimization minimizes a cost function representing a complexity of the modeled performance parameter distribution subject to a constraint that substantially all points comprised within the measurement data are within a threshold value from the modeled performance parameter distribution.
17. The method according to clause 16, wherein, where the measurement data comprises one or more outliers, said one or more outliers are allowed not to satisfy the constraint, and the cost function further comprises a penalization term to penalize said outliers which do not satisfy the constraint.
18. A method according to clause 17, wherein the penalization term comprises one or more slack variables to accommodate any outliers comprised within the measurement data, said constraint being relaxed for said outliers.
19. A method according to clause 18, wherein the penalization term further comprises a complexity coefficient which can be selected and/or optimized to determine the degree to which the outliers are penalized against the complexity of the fitting.
20. A method according to clause 16 to 19, further comprising defining Lagrange multipliers for said cost function, and converting the cost function into a Lagrangian function using the Lagrange multipliers.
21. A method according to clause 20, comprising converting the Lagrangian function into quadratic programming optimization.
22. A method according to clause 20 or 21, wherein said modeling step comprises determining model parameters as a linear combination of a design matrix and optimized values for said Lagrange multipliers.
23. A method of determining a function describing a performance parameter distribution comprising:
   obtaining measurement data relating to a performance parameter for sampling locations on a substrate;
   determining a kernel; and
   performing an optimization process using the kernel to determine support vectors and support values defining the function.
24. A method according to clause 23, wherein the kernel comprises a positive semi-definite matrix.
25. A method according to clause 23 or 24, wherein the determining the kernel is at least partly based on a criterion for evaluating the measurement data.
26. A method according to any of clauses 23 to 25, further comprising generating a feature space based on a mapping function.
27. A method according to clause 26, wherein the kernel corresponding to a distance metric associated with the feature space.
28. A method according to clause 26 or 27, wherein dimensions of the feature space correspond to components of the mapping function.
29. A method according to any of clauses 26 to 28, wherein the mapping function maps the sampling locations to the feature space.
30. A method according to any of clauses 27 to 29, wherein the distance metric defines distances among elements of the feature space.
31. A method according to any of clauses 27 to 30, wherein the distance metric is derived from an inner product defined for the feature space.
32. A method according to any of clauses 23 to 31, wherein said at least one criterion comprises a measure of similarity between individual measurements of said measurement data.
33. A method according to any of clauses 23 to 32, comprising:
   generating a kernel function; and
   determining said kernel by evaluating the kernel function on one or more measurement locations of said measurement data.
34. A method according to clause 33, wherein said kernel function is generated analytically.
35. A method according to any of clauses 23 to 34, wherein said performing an optimization process comprises performing a kernel based support vector machines regression using said kernel.
36. A method according to any of clauses 23 to 35, wherein the kernel based support vector machines regression comprises modeling the measurement data using the kernel by minimizing a complexity metric applied to coefficients of the support vectors while not allowing a deviation between the measurement data and the function to exceed a threshold value.
37. A method according to clause 35 or 36, wherein said optimization process comprises solving the kernel based support vector machines regression to yield said function.
38. A method according to any of clauses 23 to 37, wherein said function comprises a non-parametric function.
39. A method according to any of clauses 23 to 38, wherein said kernel is constructed such that it corresponds to an infinite dimensional parametric model.
40. A method according to any of clauses 23 to 39, wherein said kernel is constructed such that it corresponds to one or more classes of models.
41. A method according to clause 40, wherein the class of model describes a level of granularity of a model.
42. A method according to clause 40 or 41, wherein said kernel is constructed such that it corresponds to a plurality of classes of models.
43. A method according to any of clauses 23 to 42, wherein said kernel comprises a Gaussian kernel, a polynomial kernel, and/or a discrete kernel.
44. A computer program comprising program instructions operable to perform the method of any of clauses 1 to 43, when run on a suitable apparatus.
45. A non-transient computer program carrier comprising the computer program of clause 44.
46. A processing device comprising storage means, said storage means comprising the computer program of clause 36; and
   a processor operable to perform the method of any of clauses 1 to 43 responsive to said computer program.
47. A lithographic apparatus configured to provide product structures to a substrate in a lithographic process, comprising the processing device of clause 46.
48. A lithographic apparatus according to clause 47, further comprising:
   a substrate stage for holding the substrate;
   a patterning device stage for holding a patterning device; and
   a pattern transfer unit for transferring a pattern on said patterning device onto said substrate.
49. A lithographic apparatus according to clause 48 comprising an actuator, said actuator for at least one of said substrate stage, patterning device stage and pattern transfer unit, and operable such that said actuator is controlled based on said fitted model.
50. A lithographic cell comprising
   the lithographic apparatus of clause 47, 48 or 49; and
   a metrology system operable to measure said measurement data.

The terms “radiation” and “beam” used in relation to the lithographic apparatus encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A method of processing measurement data relating to a substrate processed by a manufacturing process, the method comprising:
obtaining measurement data relating to a performance parameter for at least a portion of the substrate; and
fitting, by a hardware computer system, the measurement data to a model by minimizing a complexity metric applied to fitting parameters of the model while not allowing a deviation between the measurement data and the fitted model to exceed a threshold value.

2. The method as claimed in claim 1, wherein the complexity metric is 1-norm or 2-norm of the model parameters, or is 1-norm or 2-norm of weighted model parameters.

3. The method as claimed in claim 1, wherein the complexity metric further comprises:
one or more slack variables to accommodate any one or more outliers comprised within the measurement data, the deviation between the measurement data and the fitted model being allowed to exceed the threshold value for the one or more outliers, and
one or more coefficients for weighting the slack variables.

4. The method as claimed in claim 3, wherein the one or more coefficients is a complexity coefficient which can be selected and/or optimized to determine the degree to which the one or more outliers are penalized against the complexity of the fitting.

5. The method as claimed in claim 1, wherein the measurement data comprises at least two-dimensional measurement data.

6. The method as claimed in claim 5, wherein the fitting comprises determining a two-dimensional fingerprint describing a spatial distribution of the performance parameter.

7. The method as claimed in claim 1, further comprising defining Lagrange multipliers for the complexity metric, converting the complexity metric into a Lagrangian function using the Lagrange multipliers and converting the Lagrangian function into a quadratic programming optimization.

8. The method as claimed in claim 7, wherein the fitting comprises determining model parameters as a linear combination of a design matrix and optimized values for Lagrange multipliers.

9. The method as claimed in claim 1, wherein the measurement data describes one or more selected from: a characteristic of the substrate; a characteristic of a patterning device which defines a pattern which is to be applied to the substrate; a position of one or both of a substrate stage for holding the substrate and a reticle stage for holding the patterning device; or a characteristic of a pattern transfer system which transfers the pattern on the patterning device to the substrate.

10. The method as claimed in claim 1, wherein the measurement data comprises one or more selected from: overlay data, critical dimension data, alignment data, focus data, or levelling data.

11. The method as claimed in claim 1, wherein the complexity metric relates to controlling a lithographic process of the manufacturing process, to optimize control of one or more selected from: exposure trajectory control in directions parallel to a substrate plane; exposure trajectory control in a direction perpendicular to the substrate plane; lens aberration corrections; dose control; or laser bandwidth control for a source laser of a lithographic apparatus.

12. The method as claimed in claim 11, further comprising controlling the lithographic process according to the optimized control.

13. The method as claimed in claim 11, wherein the lithographic process comprises exposure of a layer on a substrate, and the manufacturing process is for manufacturing an integrated circuit.

14. The method as claimed in claim 1, wherein the complexity metric is operable to minimize one or more selected from: overlay error, edge placement error, critical dimension error, focus error, alignment error or levelling error.

15. A non-transient computer program carrier comprising program instructions therein, the instructions, when executed by an apparatus, configured to cause the apparatus to at least:
obtain measurement data relating to a performance parameter for at least a portion of the substrate processed by a manufacturing process; and
fit the measurement data to a model by minimizing a complexity metric applied to fitting parameters of the model while not allowing a deviation between the measurement data and the fitted model to exceed a threshold value.

16. The carrier of claim 15, wherein the complexity metric is 1-norm or 2-norm of the model parameters, or is 1-norm or 2-norm of weighted model parameters.

17. The carrier of claim 15, wherein the complexity metric further comprises:
one or more slack variables to accommodate any one or more outliers comprised within the measurement data, the deviation between the measurement data and the fitted model being allowed to exceed the threshold value for the one or more outliers, and
one or more coefficients for weighting the slack variables.

18. The carrier of claim 17, wherein the one or more coefficients is a complexity coefficient which can be selected and/or optimized to determine the degree to which the one or more outliers are penalized against the complexity of the fitting.

19. The carrier of claim 15, wherein the complexity metric relates to control of a lithographic process of the manufacturing process, to optimize control of one or more selected from: exposure trajectory control in directions parallel to a substrate plane; exposure trajectory control in a direction perpendicular to the substrate plane; lens aberration correction; dose control; or laser bandwidth control for a source laser of a lithographic apparatus.

20. The carrier of claim 15, wherein the instructions are further configured to cause the apparatus to cause control of the lithographic process according to the optimized control.
